(19) United States
(12) Patent Application Publication
(10) Pub. No.: US 2026/0262427 A1
(43) Pub. Date: Sep. 3, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Ruoxiang Li, Beijing (CN); Yao Hu, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/994,766

(22) PCT Filed: May 28, 2024
(86) PCT No.: PCT/CN2024/095831

§ 371 Date: Jan. 15, 2025

(30) Foreign Application Priority Data
May 29, 2023 (CN) 202310621037.5

(51) Int. Cl. H10K 59/80; H10H 29/37; H10H 29/85; H10H 29/853; H10H 29/855; H10K 59/122; H10K 59/38; H10K 59/60; H10K 102/00

(52) U.S. Cl. CPC H10K 59/8792; H10H 29/37; H10H 29/8517; H10H 29/853; H10H 29/8552; H10K 59/122; H10K 59/38; H10K 59/60; H10K 59/873; H10K 2102/351

(57) ABSTRACT

A display panel and a display apparatus are provided, wherein the display panel includes a display region and a peripheral region surrounding the display region, the display region includes a light-transmitting area and a non-light-transmitting area located at at least one side of the light-transmitting area, and the light-transmitting area is configured to transmit infrared light; the display panel includes: a light-emitting substrate, including a light-emitting area and a non-light-emitting area; and a light-shielding layer located at a light-emitting side of the light-emitting substrate, an orthographic projection of the light-shielding layer on the light-emitting substrate is located in the non-light-emitting area.

### CROSS-REFERENCE TO RELATED APPLICATION

This application claims the priority of the Chinese Patent application filed on May 29, 2023 before the China National Intellectual Property Administration with the application number of 202310621037.5, and the title of “DISPLAY PANEL AND DISPLAY DEVICE”, which is incorporated herein in its entirety by reference.

### FIELD

The present disclosure relates to the technical field of displaying and, more particularly, to a display panel and a display apparatus.

### BACKGROUND

In order to reduce the reflection of ambient light from an organic light-emitting diode (OLED) display panel, a color filter may be disposed at the outer side of an encapsulation layer of the display panel, the light emitting efficiency may be improved and the power consumption may be reduced compared with the manner of attaching a polarizer to the surface of the display panel.

### SUMMARY

A display panel is provided by the present disclosure, which includes a display region and a peripheral region surrounding the display region, the display region includes a light-transmitting area and a non-light-transmitting area located at at least one side of the light-transmitting area, and the light-transmitting area is configured to transmit infrared light; the display panel includes:
a light-emitting substrate, including a light-emitting area and a non-light-emitting area;
a light-shielding layer located at a light-emitting side of the light-emitting substrate, an orthographic projection of the light-shielding layer on the light-emitting substrate being located in the non-light-emitting area;
wherein the light-shielding layer includes: a first light-shielding pattern located in the light-transmitting area and a second light-shielding pattern located in the non-light-transmitting area; and a transmittance of the first light-shielding pattern for infrared light is greater than a transmittance of the first light-shielding pattern for visible light.

In some embodiments, the transmittance of the first light-shielding pattern for the infrared light is greater than or equal to a transmittance of the second light-shielding pattern for the infrared light.

In some embodiments, a material of the first light-shielding pattern includes an organic pigment.

In some embodiments, a material of the second light-shielding pattern includes at least one of an organic pigment and an inorganic pigment.

In some embodiments, a carbon content of the first light-shielding pattern is less than a carbon content of the second light-shielding pattern.

In some embodiments, a material of the first light-shielding pattern is the same as a material of the second light-shielding pattern; and
a thickness of the first light-shielding pattern is greater or less than a thickness of the second light-shielding pattern.

In some embodiments, the light-emitting substrate includes:
a base substrate;
a pixel definition layer located at a side of the base substrate close to the light-shielding layer;
wherein the pixel definition layer includes: a pixel opening, a first definition pattern located in the light-transmitting area, and a second definition pattern located in the non-light-transmitting area; the pixel opening is configured to dispose a light-emitting device to form the light-emitting area; a transmittance of the first definition pattern for the infrared light is greater than or equal to a transmittance of the second definition pattern for the infrared light.

In some embodiments, a transmittance of the first definition pattern for the visible light is greater than or equal to a transmittance of the second definition pattern for the visible light.

In some embodiments, a material of the first definition pattern is the same as a material of the second definition pattern; and
a thickness of the first definition pattern is greater or less than a thickness of the second definition pattern.

In some embodiments, a color of the first light-shielding pattern, a color of the second light-shielding pattern and a color of the second definition pattern are black, and a color of the first definition pattern is black or transparent.

In some embodiments, the pixel opening includes: a first pixel opening located in the light-transmitting area and a second pixel opening located in the non-light-transmitting area; the first pixel opening and the second pixel opening are configured to dispose light-emitting devices with the same light-emitting color; and an opening size of the first pixel opening is less than or equal to an opening size of the second pixel opening.

In some embodiments, the opening size of the first pixel opening is equal to the opening size of the second pixel opening; a transmittance of the first definition pattern for the visible light is greater than a transmittance of the second definition pattern for the visible light; and a material of the first light-shielding pattern is the same as a material of the second light-shielding pattern, and a thickness of the first light-shielding pattern is greater than a thickness of the second light-shielding pattern.

In some embodiments, the opening size of the first pixel opening is less than the opening size of the second pixel opening; a material of the first light-shielding pattern is the same as a material of the second light-shielding pattern, and a material of the first definition pattern is the same as a material of the second definition pattern; and
a thickness of the first light-shielding pattern is less than a thickness of the second light-shielding pattern, and/or a thickness of the first definition pattern is less than a thickness of the second definition pattern.

In some embodiments, the transmittance of the first definition pattern for the infrared light is greater than or equal to 20%.

In some embodiments, the transmittance of the first light-shielding pattern for the infrared light is greater than or equal to 20%, and the transmittance of the first light-shielding pattern for the visible light is less than or equal to 20%.

In some embodiments, the display panel further includes an encapsulation layer located between the light-emitting substrate and the light-shielding layer, and the encapsulation layer is configured to isolate the light-emitting substrate from water and oxygen.

In some embodiments, the display panel further includes a touch layer located between the encapsulation layer and the light-shielding layer, and the touch layer includes a touch electrode.

In some embodiments, the display panel further includes a light filtering layer located at a side of the light-shielding layer away from the light-emitting substrate, and the light filtering layer fills openings of the light-shielding layer; an orthographic projection of the light filtering layer on the light-emitting substrate covers the light-emitting area.

A display apparatus is provided by the present disclosure, including:
the display panel according to any one of embodiments stated above;
an infrared light source located at at least one side of the display panel and configured to emit infrared light;
an infrared photosensitive device disposed away from a light-emitting side of the display panel and configured to receive infrared light reflected by an external object;
wherein the light-transmitting area is configured to transmit infrared light emitted by the infrared light source and/or infrared light reflected by the external object.

In some embodiments, the infrared light source and the infrared photosensitive device are located on a backlight surface of the display panel.

The above description is only a summary of technical schemes of the present disclosure, which can be implemented according to contents of the specification in order to better understand technical means of the present disclosure; and in order to make above and other objects, features and advantages of the present disclosure more obvious and understandable, detailed description of the present disclosure is particularly provided in the following.

### BRIEF DESCRIPTION OF THE DRAWINGS

In order to more clearly illustrate the technical solutions of the embodiments of the present disclosure or the prior art, the figures that are required to describe the embodiments or the prior art may be briefly introduced below. Apparently, the figures that are described below are embodiments of the present disclosure, and a person skilled in the art can obtain other figures according to these figures without paying creative work. It should be noted that the proportions in the drawings are only indicative and do not represent actual proportions.

FIG. 1 exemplarily shows a schematic cross-sectional structural diagram of a display panel in the related art;

FIG. 2 exemplarily shows a schematic cross-sectional structural diagram of a first display panel according to the present disclosure;

FIG. 3 exemplarily shows a schematic cross-sectional structural diagram of a second display panel according to the present disclosure;

FIG. 4 exemplarily shows a schematic cross-sectional structural diagram of a third display panel according to the present disclosure;

FIG. 5 exemplarily shows a schematic cross-sectional structural diagram of a fourth display panel according to the present disclosure;

FIG. 6 exemplarily shows a schematic cross-sectional structural diagram of a fifth display panel according to the present disclosure;

FIG. 7 exemplarily shows a schematic cross-sectional structural diagram of a sixth display panel according to the present disclosure;

FIG. 8 exemplarily shows a schematic cross-sectional structural diagram of a seventh display panel according to the present disclosure;

FIG. 9 exemplarily shows a schematic planar structural diagram of a seventh display panel according to the present disclosure; and

FIG. 10 exemplarily shows a schematic planar structural diagram of a display apparatus according to the present disclosure.

### DETAILED DESCRIPTION

In order to make the object, technical solutions, and advantages of the embodiments of the present disclosure clearer, the technical solutions in the embodiments of the present disclosure will be clearly and completely described below in conjunction with the accompanying drawings in the embodiments of the present disclosure. Obviously, the described embodiments are only some embodiments of the present disclosure, not all embodiments. Based on the embodiments of the present disclosure, all other embodiments obtained by a person skilled in the art without involving inventive effort fall within the scope of the present disclosure.

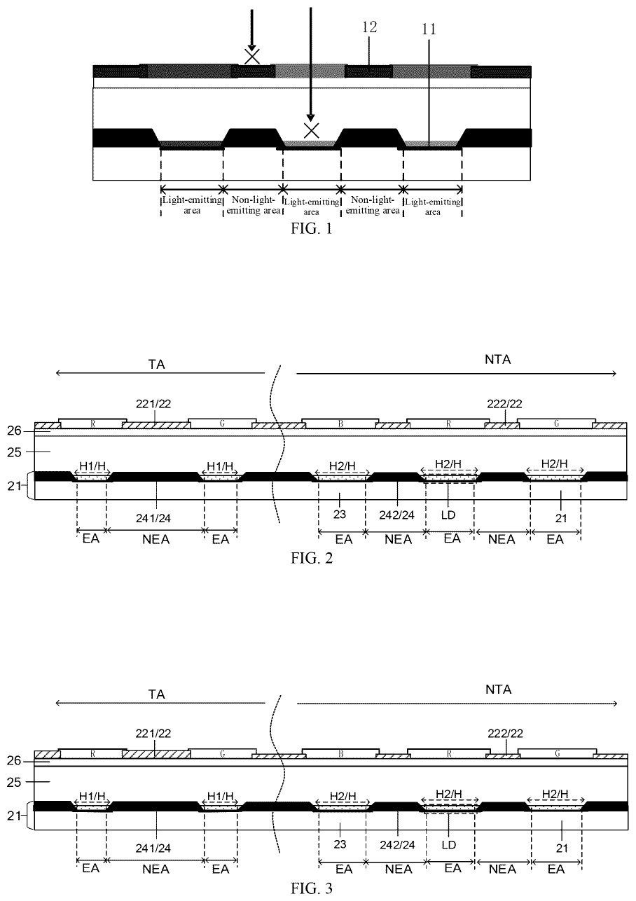

Referring to FIG. 1, a display panel is exemplarily shown. As shown in FIG. 1, by disposing a color-filter on encapsulation (COE) at a light-emitting side of the display panel, the ambient light reflection may be reduced and the contrast of the display panel may be improved. A light-proof anode 11 is disposed in a light-emitting area EA of the display panel, and the COE includes a black matrix 12 located in the non-light-emitting area NEA, which results in that the whole display panel cannot transmit light.

In order to solve the above-mentioned problems, as shown in FIG. 10, a display panel 101 provided by the present disclosure includes a display region AA and a peripheral region BA surrounding the display region AA. The display region AA includes a light-transmitting area TA and a non-light-transmitting area NTA located at at least one side of the light-transmitting area TA, and the light-transmitting area TA is configured to transmit infrared light. Both the light-transmitting area TA and the non-light-transmitting area NTA may display a picture.

As shown in any one of FIGS. 2 to 8, the display panel provided by the present disclosure includes: a light-emitting substrate 21, including a light-emitting area EA and a non-light-emitting area NEA; and a light-shielding layer 22 located at a light-emitting side of the light-emitting substrate 21, wherein an orthographic projection of the light-shielding layer 22 on the light-emitting substrate 21 is located in the non-light-emitting area NEA. The light-shielding layer 22 includes: a first light-shielding pattern 221 located in the light-transmitting area TA and a second light-shielding pattern 222 located in the non-light-transmitting area NTA. A transmittance of the first light-shielding pattern 221 for infrared light is greater than a transmittance of the first light-shielding pattern 221 for visible light.

By setting that the first light-shielding pattern 221 has a large transmittance for infrared light, it can be realized that the infrared light can be transmitted in the light-transmitting area TA, which is conducive to realizing functions, such as under-screen fingerprint recognition and under-screen facial recognition.

In addition, since the first light-shielding pattern 221 has a low transmittance for visible light, the reflection of ambient light by the light-emitting substrate 21 may be reduced, and the display contrast of the light-transmitting area TA may be improved. Meanwhile, there is no need to dispose a polarizer, thereby the power consumption is reduced.

In some embodiments, the transmittance of the first light-shielding pattern 221 for the infrared light is greater than or equal to 20%. Further, the transmittance of the first light-shielding pattern 221 for the infrared light may be greater than or equal to 50%, 60%, 70%, 80%, 85% or 90%.

In some embodiments, the transmittance of the first light-shielding pattern 221 for visible light is less than or equal to 20%. Further, the transmittance of the first light-shielding pattern 221 for visible light may be less than or equal to 10% or 5%.

Exemplarily, the first light-shielding pattern 221 has an optical density (OD) value at 550 nm, i.e., OD@550 nm≥1.0.

In some embodiments, the transmittance of the first light-shielding pattern 221 for the infrared light may be greater than or equal to the transmittance of the second light-shielding pattern 222 for the infrared light.

In order to allow the first light-shielding pattern 221 to have a high transmittance for the infrared light, in some embodiments, a material of the first light-shielding pattern 221 includes an organic pigment.

Exemplarily, the material of the first light-shielding pattern 221 may include a host material and an organic pigment doped in the host material. For example, the host material of the first light-shielding pattern 221 may be an acrylic material or a resin material such as siloxane. For example, the organic pigment may be an organic black pigment.

In some embodiments, a material of the second light-shielding pattern 222 includes at least one of the following: an organic pigment and an inorganic pigment.

Exemplarily, the material of the second light-shielding pattern 222 may include a host material and a pigment doped in the host material. For example, the host material of the second light-shielding pattern 222 may be an acrylic material or a resin material such as siloxane, and the pigment may include one or two of an organic pigment and an inorganic pigment. For example, the organic pigment may be an organic black pigment, and the inorganic pigment may be a carbon black pigment.

In some embodiments, a carbon content of the first light-shielding pattern 221 is less than a carbon content of the second light-shielding pattern 222. The carbon content of the first light-shielding pattern 221 may be 0.

Exemplarily, the material of the first light-shielding pattern 221 and the material of the second light-shielding pattern 222 include a carbon black pigment, and a doping ratio of the carbon black pigment in the first light-shielding pattern 221 is less than a doping ratio of the carbon black pigment in the second light-shielding pattern 222. The doping ratio of the carbon black pigment in the first light-shielding pattern 221 may be 0.

Exemplarily, the material of the first light-shielding pattern 221 and the material of the second light-shielding pattern 222 include an organic black pigment, and a doping ratio of the organic black pigment in the first light-shielding pattern 221 is greater than a doping ratio of the organic black pigment in the second light-shielding pattern 222. The doping ratio of the organic black pigment in the second light-shielding pattern 222 may be 0.

In some embodiments, the material of the first light-shielding pattern 221 is the same as the material of the second light-shielding pattern 222.

Exemplarily, the material of the first light-shielding pattern 221 and the material of the second light-shielding pattern 222 include the same host material and the organic black pigment doped in the host material.

In some embodiments, the material of the first light-shielding pattern 221 is different from the material of the second light-shielding pattern 222.

Exemplarily, the material of the first light-shielding pattern 221 includes the organic black pigment, and the material of the second light-shielding pattern 222 includes the carbon black pigment. The host material of the first light-shielding pattern 221 and the host material of the second light-shielding pattern 222 may be the same or different.

In some embodiments, as shown in FIGS. 2 to 6, a thickness of the first light-shielding pattern 221 is equal to a thickness of the second light-shielding pattern 222.

In particular implementation, in order to reduce the difference in reflectivity between the light-transmitting area TA and the non-light-transmitting area NTA, the thickness of the first light-shielding pattern 221 and the thickness of the second light-shielding pattern 222 may also be designed differently. For example, in some embodiments, the thickness of the first light-shielding pattern 221 is different from the thickness of the second light-shielding pattern 222, as shown in any one of FIGS. 3 to 5 and FIG. 7.

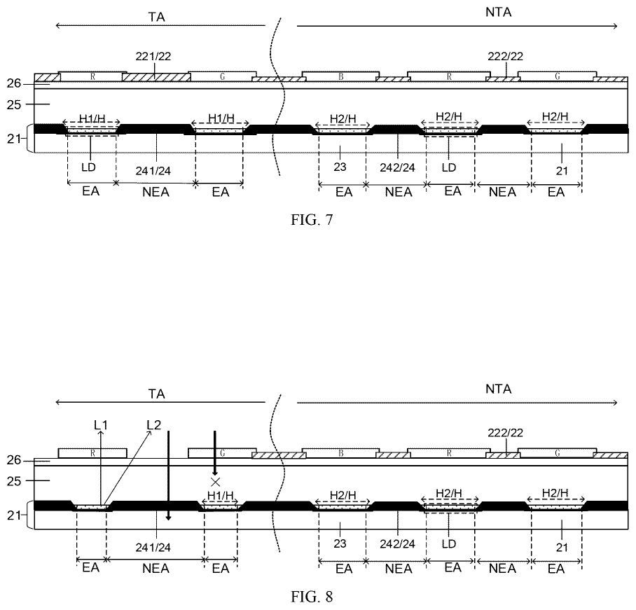

Exemplarily, as shown in FIG. 3, FIG. 5 or FIG. 7, the thickness of the first light-shielding pattern 221 is greater than the thickness of the second light-shielding pattern 222. In this way, it is conducive to reducing the reflectivity of the light-transmitting area TA.

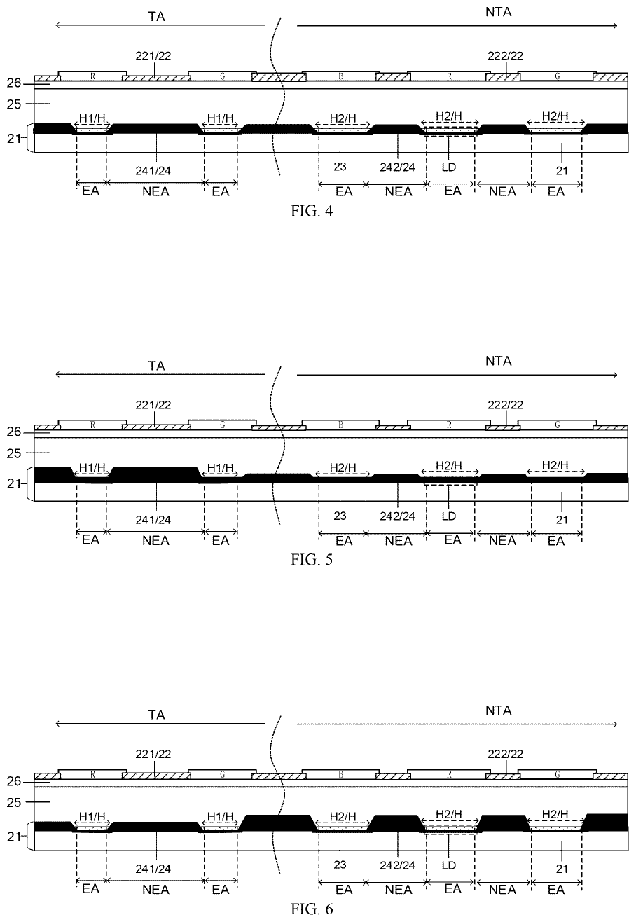

Exemplarily, as shown in FIG. 4, the thickness of the first light-shielding pattern 221 is less than the thickness of the second light-shielding pattern 222. In this way, it is conducive to increasing the reflectivity of the light-transmitting area TA, while further improving the transmittance of the light-transmitting area TA for infrared light.

In some embodiments, a color of the first light-shielding pattern 221 and a color of the second light-shielding pattern 222 are both black, which is not limited in the present disclosure.

In some embodiments, as shown in any one of FIGS. 2 to 8, the light-emitting substrate 21 includes: a base substrate 23; and a pixel definition layer 24 located at a side of the base substrate 23 close to the light-shielding layer 22. The pixel definition layer 24 includes: a pixel opening H, a first definition pattern 241 located in the light-transmitting area TA, and a second definition pattern 242 located in the non-light-transmitting area NTA. The pixel opening H is configured to dispose a light-emitting device LD to form the light-emitting area EA. A transmittance of the first definition pattern 241 for the infrared light is greater than or equal to a transmittance of the second definition pattern 242 for the infrared light.

By setting that the first definition pattern 241 has a high transmission for the infrared light, the transmittance of the light-transmitting area for the infrared light may be further improved.

Exemplarily, the defined pattern (e.g., the first definition pattern 241 or the second definition pattern 242) in the pixel definition layer 24 may be prepared by using a non-photosensitive polyimide material. The defined pattern obtained by preparing has a black color, a transmittance for the infrared light is greater than or equal to 85%, a transmittance for the visible light is less than or equal to 20%, and for example, an OD value at 550 nm, i.e., OD@550 nm≥1.0.

Exemplarily, the defined pattern (e.g., the first definition pattern 241 or the second definition pattern 242) in the pixel definition layer 24 may be prepared by using a photosensitive polyimide material. The defined pattern obtained by preparing has a transparent color, a transmittance for the infrared light is greater than or equal to 85%, and a transmittance for the visible light is greater than or equal to 85%.

In some embodiments, the transmittance of the first definition pattern 241 for the infrared light is greater than or equal to 20%. Further, the transmittance of the first definition pattern 241 for the infrared light is greater than or equal to 50%, 60%, 70%, 80%, 85% or 90%.

Exemplarily, the first definition pattern 241 may be prepared by using a photosensitive or non-photosensitive polyimide material, which is not limited in the present disclosure.

In some embodiments, the transmittance of the first definition pattern 241 for the visible light is greater than or equal to the transmittance of the second definition pattern 242 for the visible light.

Exemplarily, the first definition pattern 241 may be prepared by using a photosensitive polyimide material, and the second definition pattern 242 may be prepared by using a non-photosensitive polyimide material, so that the transmittance of the first definition pattern 241 for the visible light is greater than or equal to 85%, and the transmittance of the second definition pattern 242 for the visible light is less than or equal to 20%.

In some embodiments, the material of the first definition pattern 241 is the same as the material of the second definition pattern 242.

Exemplarily, both the first definition pattern 241 and the second definition pattern 242 are prepared by using the same polyimide, such as a non-photosensitive polyimide material.

In other implementations, the material of the first definition pattern 241 is different from the material of the second definition pattern 242.

Exemplarily, the first definition pattern 241 and the second definition pattern 242 are prepared by using different polyimide materials. For example, the first definition pattern 241 may be prepared by using the photosensitive polyimide material, and the second definition pattern 242 may be prepared by using the non-photosensitive polyimide material.

The first definition pattern 241 prepared by using the photosensitive polyimide material has a higher transmittance for the infrared light, and the transmittance of the light-transmitting area TA for the infrared light may be further improved.

The first definition pattern 241 prepared by using the non-photosensitive polyimide material has a lower transmittance for the visible light, the reflection of the ambient light by the light-emitting substrate 21 may be reduced, and the contrast of the display image in the light-transmitting area TA may be improved.

In some embodiments, as shown in any one of FIGS. 2 to 4 and 7 to 8, a thickness of the first definition pattern 241 is equal to a thickness of the second definition pattern 242.

In particular implementations, in order to reduce the difference in reflectivity between the light-transmitting area TA and the non-light-transmitting area NTA, the thickness of the first definition pattern 241 and the thickness of the second definition pattern 242 may also be designed differently. For example, in some embodiments, the thickness of the first definition pattern 241 is different from the thickness of the second definition pattern 242, as shown in FIG. 5 or FIG. 6.

Exemplarily, as shown in FIG. 5, the thickness of the first definition pattern 241 is greater than the thickness of the second definition pattern 242. In this way, it is conducive to reducing the reflectivity of the light-transmitting area TA.

Exemplarily, as shown in FIG. 6, the thickness of the first definition pattern 241 is less than the thickness of the second definition pattern 242. In this way, it is conducive to increasing the reflectivity of the light-transmitting area TA, while further improving the transmittance of the light-transmitting area TA for the infrared light.

In some embodiments, a color of the first definition pattern 241 is black or transparent, and a color of the second definition pattern 242 is black.

Exemplarily, the first definition pattern 241 is prepared by using the photosensitive polyimide material, and the color of the first definition pattern 241 is transparent. Alternatively, the first definition pattern 241 is prepared by using the non-photosensitive polyimide material, and the color of the first definition pattern 241 is black.

Exemplarily, the second definition pattern 242 may also be prepared by using the non-photosensitive polyimide material, and the color of the second definition pattern 242 is black.

Exemplarily, the transparent color may be transparent red, transparent orange, transparent yellow, or the like.

In some embodiments, as shown in any one of FIGS. 2 to 8, the pixel openings H include: a first pixel opening H1 located in the light-transmitting area TA and a second pixel opening H2 located in the non-light-transmitting area NTA. The first pixel opening HI and the second pixel opening H2 are configured to dispose light-emitting devices LDs with the same light-emitting color. An opening size of the first pixel opening HI is less than an opening size of the second pixel opening H2 (as shown in any one of FIGS. 1 to 6 and FIG. 8), or the opening size of the first pixel opening HI is equal to the opening size of the second pixel opening H2 (as shown in FIG. 7).

Since the area of the pixel opening H cannot transmit the infrared light, and the first definition pattern 241 can transmit the infrared light, disposing the first pixel opening H1 with a small opening size in the light-transmitting area TA is equivalent to increasing the area of the first definition pattern 241, so that the transmittance of the light-transmitting area TA for the infrared light may be further improved.

In some embodiments, as shown in FIG. 7, the opening size of the first pixel opening H1 is equal to the opening size of the second pixel opening H2, the transmittance of the first definition pattern 241 for the visible light is greater than the transmittance of the second definition pattern 242 for the visible light, and the material of the first light-shielding pattern 221 is the same as the material of the second light-shielding pattern 222. In this case, the reflectivity of the light-transmitting area TA for the ambient light is greater than the reflectivity of the non-light-transmitting area NTA for the ambient light. In order to reduce the difference in reflectivity between the light-transmitting area TA and the non-light-transmitting area NTA for the ambient light, the thickness of the first light-shielding pattern 221 may be set to be greater than the thickness of the second light-shielding pattern 222.

In some embodiments, as shown in any one of FIGS. 1 to 6 and FIG. 8, the opening size of the first pixel opening H1 is less than the opening size of the second pixel opening H2, the material of the first light-shielding pattern 221 is the same as the material of the second light-shielding pattern 222, and the material of the first definition pattern 241 is the same as the material of the second definition pattern 242. In this case, the reflectivity of the light-transmitting area TA for the ambient light is less than the reflectivity of the non-light-transmitting area NTA for the ambient light. In order to reduce the difference in reflectivity between the light-transmitting area TA and the non-light-transmitting area NTA for the ambient light, the thickness of the first light-shielding pattern 221 may be set to be less than the thickness of the second light-shielding pattern 222 (as shown in FIG. 4), or the thickness of the first definition pattern 241 may be set to be less than the thickness of the second definition pattern 242 (as shown in FIG. 6). Alternatively, the thickness of the first light-shielding pattern 221 is less than the thickness of the second light-shielding pattern 222, and the thickness of the first definition pattern 241 is less than the thickness of the second definition pattern 242.

In some embodiments, the material of the first light-shielding pattern 221 is the same as the material of the second light-shielding pattern 222. As shown in any one of FIGS. 1 to 6 and FIG. 8, the opening size of the first pixel opening HI is less than the opening size of the second pixel opening H2, and the transmittance of the first definition pattern 241 for the visible light is greater than the transmittance of the second definition pattern 242 for the visible light. The first pixel opening H1 with a small opening size may reduce the reflectivity of the light-transmitting area TA for the ambient light, and meanwhile, the first definition pattern 241 having a high transmittance for the visible light may increase the reflectivity of the light-transmitting area TA for the ambient light. In this case, whether there is a difference in reflectivity between the light-transmitting area TA and the non-light-transmitting area NTA for the ambient light may be determined through simulation software. If there is a difference, the thickness of the first light-shielding pattern 221 and the thickness of the second light-shielding pattern 222 may be designed differently, and/or the thickness of the first definition pattern 241 and the thickness of the second definition pattern 242 may be designed differently, so as to reduce the difference in reflectivity between the light-transmitting area TA and the non-light-transmitting area NTA for the ambient light.

Exemplarily, the light-emitting device LD may be, for example, an organic light-emitting diode (OLED), a quantum dot light-emitting diode (QLED), a mini light-emitting diode (Mini LED), or a micro light-emitting diode (Micro LED).

In some embodiments, as shown in any one of FIGS. 2 to 8, the display panel further includes an encapsulation layer 25, the encapsulation layer 25 is located between the light-emitting substrate 21 and the light-shielding layer 22. The encapsulation layer 25 is configured to protect the light-emitting substrate 21 and isolate the light-emitting substrate 21 from water and oxygen, thereby the performance stability of the light-emitting substrate 21 is improved and the service life of the display panel is prolonged.

In some embodiments, as shown in any one of FIGS. 2 to 8, the display panel further includes a touch layer 26 located between the encapsulation layer 25 and the light-shielding layer 22. The touch layer 26 may include a touch electrode configured to make the display panel have a touch function.

Since the reflection of the ambient light by the touch electrode is significant, disposing the light-shielding layer 22 at a side of the touch layer 26 away from the light-emitting substrate 21 may also reduce the reflection of the ambient light by the touch electrode.

It should be noted that the touch electrode may also be integrated inside the light-emitting substrate 21, which is not limited in the present disclosure.

In some embodiments, as shown in any one of FIGS. 2 to 8, the display panel further includes: a light filtering layer RGB located at a side of the light-shielding layer 22 away from the light-emitting substrate 21, and the light filtering layer RGB fills openings of the light-shielding layer 22. An orthographic projection of the light filtering layer RGB on the light-emitting substrate 21 covers the light-emitting area EA. The light filtering layer RGB is configured to transmit the visible light of a preset waveband. The opening of the light-shielding layer 22 completely penetrates the light-shielding layer 22 in a normal direction of the light-emitting substrate 21.

Exemplarily, the light filtering layer RGB includes a red light filtering pattern R, a green light filtering pattern G, and a blue light filtering pattern B. The red light filtering pattern R is configured to transmit red light in the visible light, the green light filtering layer G is configured to transmit green light in the visible light, and the blue light filtering layer B is configured to transmit blue light in the visible light.

In some embodiments, in order to improve the transmittance of the light-transmitting area TA for the infrared light, the first light-shielding pattern 221 of the light-transmitting area TA may also be removed, i.e., the orthographic projection of the light-shielding layer 22 on the light-emitting substrate 21 does not overlap with the light-transmitting area TA, as shown in FIG. 8, in this way, the transmission of the infrared light in the light-transmitting area TA may be realized.

In the present embodiment, small-viewing-angle light L1 emitted from the light-emitting area EA passes through the light filtering layer RGB and is emitted. As the viewing angle increases, it reaches large-viewing-angle light L2, which is emitted directly without passing through the light filtering layer RGB and the light-shielding layer 22, leading to changes in color coordinates. From the perspective of the user, the screen color deviation will obviously change abruptly as the viewing angle increases.

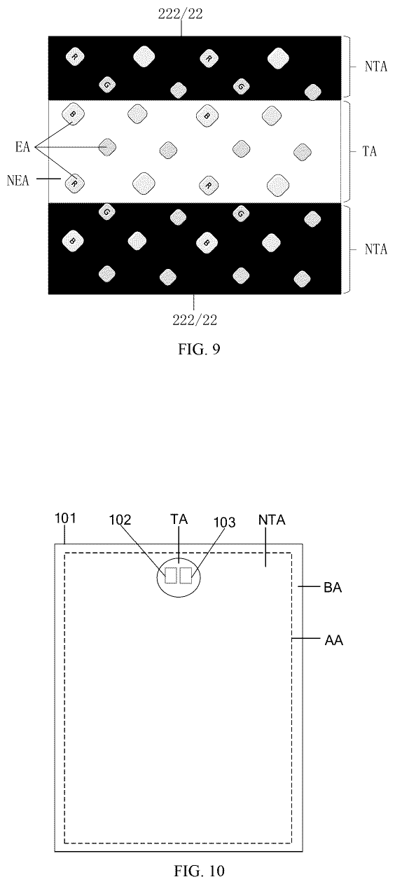

In addition, since the light-transmitting area TA is not provided with a light-shielding layer 22, the reflectivity of the light-emitting substrate 21 in the light-transmitting area TA for ambient light increases, resulting in the large difference in reflectivity or hue between the light-transmitting area TA and the non-light-transmitting area NTA, as shown in FIG. 9.

By disposing the first light-shielding pattern 221 capable of transmitting the infrared light in the light-transmitting area TA, on one hand, the reflectivity of the light-emitting substrate 21 in the light-transmitting area TA for the ambient light may be reduced and the display contrast in the light-transmitting area TA is improved, on the other hand, the display panel is enabled to partially transmit the infrared light, and meanwhile, the problems of an abrupt color deviation and a large difference in reflectivity or hue between the light-transmitting area TA and the non-light-transmitting area NTA can be avoided.

A display apparatus is provided by the present disclosure. As shown in FIG. 10, the display apparatus includes: a display panel 101 according to any one of the embodiments stated above; and at least one of: an infrared light source 102 located at at least one side of the display panel 101 and configured to emit infrared light; and an infrared photosensitive device 103 disposed away from a light-emitting side of the display panel 101 and configured to receive infrared light reflected by an external object. The light-transmitting area TA is configured to transmit the infrared light emitted by the infrared light source 102 and/or the infrared light reflected by the external object.

It can be appreciated by a person skilled in the art that the display apparatus provided by the present disclosure has the advantages of the above-mentioned display panel 101.

The display apparatus provided by the present disclosure may be any product or component with a display function, such as a mobile phone, a tablet computer, a television, a displayer, a notebook computer, a digital photo frame, a navigator, a smart watch, a fitness wrist strap, and a personal digital assistant.

Exemplarily, as shown in FIG. 10, the infrared light source 102 and the infrared photosensitive device 103 are both located on a backlight surface of the display panel 101. Further, the infrared light source 102 and the infrared photosensitive device 103 may both be located in the light-transmitting area TA. The infrared light source 102 located on the backlight surface of the display panel 101 emits infrared light, and the infrared light passes through the light-transmitting area TA and is incident on the external object. After being reflected by the external object, the infrared light again passes through the light-transmitting area TA and is incident on the infrared photosensitive device 103.

The infrared photosensitive device 103 may receive infrared light reflected by the external object and convert a received infrared light signal into an electrical signal. If the external object is a finger of the user, a fingerprint image may be generated according to the electrical signal, and then fingerprint identification may be performed. If the external object is a face of the user, a facial image may be generated according to the electric signal, and then facial recognition may be performed.

It should be noted that the infrared light source 102 may also be located at a side of the display panel 101, which is not limited in the present disclosure.

In the present disclosure, the meaning of “plurality of”′ is “two or more”, and the meaning of “at least one” is “one or more”, unless explicitly and particularly defined otherwise.

In the present disclosure, the terms that indicate orientation or position relations, such as “upper” and “lower”, are based on the orientation or position relations shown in the drawings, and are merely for conveniently describing the present disclosure and simplifying the description, rather than indicating or implying that the device or element must have the specific orientation and be constructed and operated according to the specific orientation. Therefore, they should not be construed as a limitation on the present disclosure.

In the present text, the terms “include”, “contain” or any variants thereof are intended to cover non-exclusive inclusions, so that processes, methods, articles or devices that include a series of elements do not only include those elements, but also include other elements that are not explicitly listed, or include the elements that are inherent to such processes, methods, articles or devices. Unless further limitation is set forth, an element defined by the wording “including a . . . ” does not exclude additional same element in the process, method, article or device including the element.

The “one embodiment”, “some embodiments”, “exemplary embodiments”, “one or more embodiments”, “example”, “one example” or “some examples” as used herein are intended to indicate that specific features, structures, materials or characteristics related to the embodiment or example are included in at least one embodiment or example of the present disclosure. The illustrative indication of the above terms does not necessarily refer to the same one embodiment or example. Moreover, the specific features, structures, materials or characteristics may be included in any one or more embodiments or examples in any suitable manner.

In the present text, relation terms such as first and second are merely intended to distinguish one entity or operation from another entity or operation, and that does not necessarily require or imply that those entities or operations have therebetween any such actual relation or order.

In the description on some embodiments, “couple” and “connect” may be used. For example, in the description on some embodiments, the term “connect” may be used to indicate that two or more components directly physically contact or electrically contact each other. As another example, in the description on some embodiments, the term “couple” may be used to indicate that two or more components directly physically contact or electrically contact each other. However, the term “couple” or “communicatively couple” may also indicate that two or more components do not directly contact each other, but still cooperate with each other or act on each other. The embodiments disclosed herein are not necessarily limited by the contents herein.

“At least one of A, B and C” and “at least one of A, B or C” have the same meaning, and both of them include the following combinations of A, B and C: solely A, solely B, solely C, the combination of A and B, the combination of A and C, the combination of B and C, and the combination of A, B and C.

“A and/or B” include the following three combinations: solely A, solely B, and the combination of A and B.

As used herein, with reference to the context, the term “if” is optionally interpreted as meaning “when” or “in response to determining that” or “in response to detecting that”. Similarly, with reference to the context, the phrase “if it has been determined that” or “if the stated condition or event has been detected” is optionally interpreted as referring to “when it has been determined that” or “in response to determining . . . ” or “when the stated condition or event has been detected” or “in response to the stated condition or event having been detected”.

The “for” or “configured for” as used herein is intended as opened and inclusive languages, and does not exclude apparatuses adapted for or configured for executing additional tasks or steps.

The “based on” or “according to” as used herein means opening and inclusive. The processes, steps, calculations or other actions based on one or more conditions or values may be based on other conditions or exceed the values in practice. The processes, steps, calculations or other actions according to one or more conditions or values may be according to other conditions or exceed the values in practice.

As used herein, “about”, “substantially” or “approximately” includes the described value and the average value within an acceptable deviation range of the particular value, wherein the acceptable deviation range is decided by the discussed measurement that a person skilled in the art has taken into consideration and the error relevant to the measurement on the specific quantity (i.e., the limitation of the measuring system).

As used herein, “parallel”, “perpendicular”, “equal” and “flushing” include the described case and cases similar to the described case, wherein the range of the similar cases is within an acceptable deviation range, wherein the acceptable deviation range is decided by the discussed measurement that a person skilled in the art has taken into consideration and the error relevant to the measurement on the specific quantity (i.e., the limitation of the measuring system). For example, “parallel” includes absolute parallelism and approximate parallelism, wherein the acceptable deviation range of the approximate parallelism may, for example, be deviations within 5°. “Perpendicular” includes absolute perpendicularity and approximate perpendicularity, wherein the acceptable deviation range of the approximate perpendicularity may also, for example, be deviations within 5°. “Equal” includes absolute equality and approximate equality, wherein the acceptable deviation range of the approximate equality may, for example, be that the difference between the two equal instances is less than or equal to 5% of any one of them. “Flushing” includes absolute flushing and approximate flushing, wherein the acceptable deviation range of the approximate flushing may, for example, be that the distance between the two flushing instances is less than or equal to 5% of the dimension of any one of them.

It should be understood that, when a layer or element is described as on another layer or a base board, the layer or element may be directly on the another layer or the base board, or an intermediate layer may also exist between the layer or element and the another layer or the base board.

The exemplary embodiments are described herein with reference to sectional views and/or plan views as idealized illustrative figures. In the drawings, in order for clarity, the thicknesses of the layers and the regions are exaggerated. Therefore, alterations from the shapes of the figures as the result of, for example, fabricating techniques and/or tolerances can be envisaged. Therefore, the exemplary embodiments should not be interpreted as limited to the shapes of the regions shown herein, but should include the shape deviations caused by, for example, fabrication. For example, an etching region illustrated as rectangular generally has a curved feature. Therefore, the regions shown in the drawings are essentially illustrative, and their shapes are not intended to illustrate the practical shapes of the regions of the device, and are not intended to limit the scopes of the exemplary embodiments.

Finally, it should be noted that the above embodiments are merely intended to explain the technical solutions of the present disclosure, and not to limit them. Although the present disclosure is explained in detail with reference to the above embodiments, a person skilled in the art should understand that he can still modify the technical solutions set forth by the above embodiments, or make equivalent substitutions to part of the technical features of them. However, those modifications or substitutions do not make the essence of the corresponding technical solutions depart from the spirit and scope of the technical solutions of the embodiments of the present disclosure.

1. A display panel, comprising a display region and a peripheral region surrounding the display region, the display region comprising a light-transmitting area and a non-light-transmitting area located at at least one side of the light-transmitting area, and the light-transmitting area being configured to transmit infrared light; the display panel comprising:
a light-emitting substrate, comprising a light-emitting area and a non-light-emitting area; and
a light-shielding layer located at a light-emitting side of the light-emitting substrate, an orthographic projection of the light-shielding layer on the light-emitting substrate being located in the non-light-emitting area;
wherein the light-shielding layer comprises: a first light-shielding pattern located in the light-transmitting area and a second light-shielding pattern located in the non-light-transmitting area; and a transmittance of the first light-shielding pattern for the infrared light is greater than a transmittance of the first light-shielding pattern for visible light.

2. The display panel according to claim 1, wherein the transmittance of the first light-shielding pattern for the infrared light is greater than or equal to a transmittance of the second light-shielding pattern for the infrared light.

3. The display panel according to claim 1, wherein a material of the first light-shielding pattern comprises an organic pigment.

4. The display panel according to claim 1, wherein a material of the second light-shielding pattern comprises at least one of an organic pigment and an inorganic pigment.

5. The display panel according to claim 1, wherein a carbon content of the first light-shielding pattern is less than a carbon content of the second light-shielding pattern.

6. The display panel according to claim 1, wherein a material of the first light-shielding pattern is the same as a material of the second light-shielding pattern; and
a thickness of the first light-shielding pattern is greater or less than a thickness of the second light-shielding pattern.

7. The display panel according to claim 1, wherein the light-emitting substrate comprises:
a base substrate;
a pixel definition layer located at a side of the base substrate close to the light-shielding layer;
wherein the pixel definition layer comprises: a pixel opening, a first definition pattern located in the light-transmitting area, and a second definition pattern located in the non-light-transmitting area; the pixel opening is configured to dispose a light-emitting device to form the light-emitting area; and a transmittance of the first definition pattern for the infrared light is greater than or equal to a transmittance of the second definition pattern for the infrared light.

8. The display panel according to claim 7, wherein a transmittance of the first definition pattern for the visible light is greater than or equal to a transmittance of the second definition pattern for the visible light.

9. The display panel according to claim 7, wherein a material of the first definition pattern is the same as a material of the second definition pattern; and
a thickness of the first definition pattern is greater or less than a thickness of the second definition pattern.

10. The display panel according to claim 7, wherein a color of the first light-shielding pattern, a color of the second light-shielding pattern and a color of the second definition pattern are black, and a color of the first definition pattern is black or transparent.

11. The display panel according to claim 7, wherein the pixel opening comprises: a first pixel opening located in the light-transmitting area and a second pixel opening located in the non-light-transmitting area; the first pixel opening and the second pixel opening are configured to dispose light-emitting devices with the same light-emitting color; and an opening size of the first pixel opening is less than or equal to an opening size of the second pixel opening.

12. The display panel according to claim 11, wherein the opening size of the first pixel opening is equal to the opening size of the second pixel opening; a transmittance of the first definition pattern for the visible light is greater than a transmittance of the second definition pattern for the visible light; a material of the first light-shielding pattern is the same as a material of the second light-shielding pattern, and a thickness of the first light-shielding pattern is greater than a thickness of the second light-shielding pattern.

13. The display panel according to claim 11, wherein the opening size of the first pixel opening is less than the opening size of the second pixel opening; a material of the first light-shielding pattern is the same as a material of the second light-shielding pattern, and a material of the first definition pattern is the same as a material of the second definition pattern; and
a thickness of the first light-shielding pattern is less than a thickness of the second light-shielding pattern, and/or a thickness of the first definition pattern is less than a thickness of the second definition pattern.

14. The display panel according to claim 7, wherein the transmittance of the first definition pattern for the infrared light is greater than or equal to 20%.

15. The display panel according to claim 1, wherein the transmittance of the first light-shielding pattern for the infrared light is greater than or equal to 20%, and the transmittance of the first light-shielding pattern for the visible light is less than or equal to 20%.

16. The display panel according to claim 1, wherein the display panel further comprises an encapsulation layer located between the light-emitting substrate and the light-shielding layer, and the encapsulation layer is configured to isolate the light-emitting substrate from water and oxygen.

17. The display panel according to claim 16, wherein the display panel further comprises a touch layer located between the encapsulation layer and the light-shielding layer, and the touch layer comprises a touch electrode.

18. The display panel according to claim 1, wherein the display panel further comprises a light filtering layer located at a side of the light-shielding layer away from the light-emitting substrate, and the light filtering layer fills openings of the light-shielding layer; and an orthographic projection of the light filtering layer on the light-emitting substrate covers the light-emitting area.

19. A display apparatus, comprising:
the display panel according to claim 1;
an infrared light source located at at least one side of the display panel and configured to emit infrared light;
an infrared photosensitive device disposed away from a light-emitting side of the display panel and configured to receive infrared light reflected by an external object;
wherein the light-transmitting area is configured to transmit infrared light emitted by the infrared light source and/or infrared light reflected by the external object.

20. The display apparatus according to claim 19, wherein the infrared light source and the infrared photosensitive device are located on a backlight surface of the display panel.
